(19) United States
(12) Patent Application Publication
(10) Pub. No.: US 2023/0282267 A1
(43) Pub. Date: Sep. 7, 2023

(54) POWER CONTROL CIRCUIT AND CONTROL METHOD

(71) Applicant: Changxin Memory Technologies, Inc., Hefei (CN)

(72) Inventors: Enpeng GAO, HEFEI (CN); Weibing SHANG, HEFEI (CN)

(21) Appl. No.: 17/940,723

(22) Filed: Sep. 8, 2022

(30) Foreign Application Priority Data
Jan. 14, 2022 (CN) 202210041554.0

(51) Int. Cl. G11C 11/4074; G11C 11/4076

(52) U.S. Cl. CPC G11C 11/4074; G11C 11/4076

(57) ABSTRACT

The present invention provides a power control circuit and control method. The power control circuit includes: a control module configured to control, according to an activation command, a memory bank of a plurality of memory banks to perform an operation; a power management module configured to wake up a local power supply for the memory bank according to a clock enable signal; and a power control module communicatively coupled with the power management module and configured to: send the clock enable signal to the power management module of the memory bank corresponding to the activation command in a power-saving mode; and send the clock enable signal to power management modules of the plurality of memory banks in a nonpower-saving mode, where the power-saving mode indicates that a register is configured to meet a predetermined low-frequency condition.

### CROSS-REFERENCE TO RELATED APPLICATION

This application claims priority to Chinese Patent Application No. 202210041554.0, filed with the China National Intellectual Property Administration on Jan. 14, 2022 and entitled “POWER CONTROL CIRCUIT AND CONTROL METHOD.” The above-referenced application is incorporated herein by reference in its entirety.

### TECHNICAL FIELD

The present invention relates to memory technologies, and in particular, to a power control circuit and control method.

### BACKGROUND

Memories, such as a dynamic random access memory (DRAM), are bedrocks of modern computing. Requirements for managing power consumption of memories are becoming increasingly important. There is a need to constantly improve memories to effectively reduce power consumption of memories.

### SUMMARY

Embodiments of the present invention provide a power control circuit and control method, so as to reduce power consumption of a memory.

According to some embodiments, a first aspect of the present invention provides a power control circuit, including: a control module configured to control, according to an activation command, a memory bank of a plurality of memory banks to perform an operation; a power management module configured to wake up a local power supply for the memory bank according to a clock enable signal; and a power control module communicatively coupled with the power management module and configured to: send the clock enable signal to the power management module for the memory bank corresponding to the activation command in a power-saving mode; and send the clock enable signal to power management modules of the plurality of memory banks in a non-power-saving mode, where the power-saving mode indicates that a register is configured to meet a predetermined low-frequency state.

In some embodiments, the plurality of memory banks are dynamic random access memory (DRAM), and the low-frequency condition comprises that the register is configured to enable a 16Bank mode.

In some embodiments, the low-frequency condition comprises that the register is configured to enable a dynamic voltage and frequency scaling mode.

In some embodiments, the circuit further includes: a state determining module communicatively coupled with the register and the power control module and configured to control the power control module to switch to the power-saving mode or the non-power-saving mode based on a configuration parameter of the register.

In some embodiments, the state determining module is configured to: send a first signal to the power control module to instruct the power control module to switch to the power-saving mode; and send a second signal to the power control module to instruct the power control module to switch to the non-power-saving mode.

In some embodiments, the state determining module is configured to: obtain an upper limit of a clock frequency from the configuration parameter of the register, and control, in response to the upper limit of the clock frequency being not greater than a predetermined value, the power control module to switch to the power-saving mode.

In some embodiments, the activation command is output, by a command decoding control module, to a control module of a memory bank from the plurality of memory banks at a corresponding address after the address is decoded.

In some embodiments, in the power-saving mode, the power control module is configured to send the clock enable signal to the power management module of the memory bank corresponding to the activation command by controlling a port that outputs the clock enable signal.

In some embodiments, the power control circuit further comprises a plurality of controllable switches, each being between the power control module and each of the power management modules; and in the power-saving mode, the power control module is configured to send the clock enable signal to the one power management module for the memory bank corresponding to the activation command by controlling at least some of the plurality of controllable switches to be on or off.

According to some embodiments, a second aspect of the present invention provides a power control method, applicable to a power control circuit including a control module, a power management module, and a power control module, where the method includes: controlling, by the control module according to an activation command, a memory bank of a plurality of memory banks to perform an operation; waking up, by the power management module, a local power supply of the memory bank according to a clock enable signal; and sending, by the power control module, the clock enable signal to the power management module of the memory bank corresponding to the activation command in response to a power-saving mode; and sending, by the power control module, the clock enable signal to power management modules of the plurality of memory banks in response to a non-power-saving mode, where the power-saving mode indicates that a register is configured to meet a predetermined low-frequency condition.

In some embodiments, the low-frequency condition comprises that the register is configured to enable a 16Bank mode.

In some embodiments, the low-frequency condition comprises that the register is configured to enable a dynamic voltage and frequency scaling mode.

In some embodiments, the power control circuit further includes a state determining module, and the method further includes: controlling, by the state determining module, the power control module to switch to the power-saving mode or the non-power-saving mode based on a configuration parameter of the register.

In some embodiments, the controlling, by the state determining module, the power control module to switch to the power-saving mode or the non-power-saving mode includes: sending, by the state determining module, a first signal to the power control module to instruct the power control module to switch to the power-saving mode; and sending a second signal to the power control module to instruct the power control module to switch to the non-power-saving mode.

In some embodiments, controlling, by the state determining module, the power control module to switch to the power-saving mode or the non-power-saving mode based on the configuration parameter of the register comprises: obtaining, by the state determining module, an upper limit of a clock frequency from the configuration parameter of the register, and controlling, by the state determining module, the power control module to switch to the power-saving mode in response to the upper limit of the clock frequency being not greater than a predetermined value.

In the power control circuit and control method provided in the embodiments of the present invention, the power control module switches to the power-saving mode or the non-power-saving mode based on the configuration of the register, and may select to send a clock enable signal to power management modules for some or all memory banks, so that a corresponding power management module wakes up the local power supply for the memory bank in response to the clock enable signal, and the control module controls, in response to the activation command, the memory to perform an operation, to implement a function of the memory. Based on the power control circuit, a power management mode can be switched. In the power-saving mode, only a local power supply for a selected memory bank needs to be woken up; and in the non-power-saving mode, local power supplies for all memory banks are woken up, thereby improving flexibility of power wakeup management and reducing power consumption.

### BRIEF DESCRIPTION OF DRAWINGS

The accompanying drawings, which are incorporated into and constitute a part of the description, illustrate the embodiments of the present invention and together with the description, serve to explain the principles of the embodiments of the present invention.

FIG. 1 is an exemplary diagram of a power management architecture of a memory.

FIG. 2a is a schematic structural diagram of a power control circuit according to an embodiment of the present invention.

FIG. 2b shows an exemplary power control circuit operating in a power-saving mode and a non-power-saving mode.

FIG. 3 is a schematic structural diagram of a power control circuit according to an embodiment of the present invention.

FIG. 4a and FIG. 4b show exemplary implementations of a power control module.

FIG. 5 is a schematic structural diagram of a storage device according to an embodiment of the present invention.

FIG. 6 is a schematic flowchart of a power control method according to an embodiment of the present invention.

FIG. 7 is a schematic flowchart of another power control method according to an embodiment of the present invention.

Through the above accompanying drawings, specific embodiments of the present invention have been shown and will be described in more detail below. These accompanying drawings and written descriptions are not intended to limit the scope of the concept of the present invention in any way, but to explain the concept of the present invention to persons skilled in the art by reference to specific embodiments.

### DETAILED DESCRIPTION OF EMBODIMENTS

Herein, exemplary embodiments will be described in detail, and examples thereof are shown in the accompanying drawings. When the following description refers to the accompanying drawings, unless otherwise indicated, the same reference numerals in different drawings indicate the same or similar elements. Implementations described in the following exemplary embodiments do not represent all implementations consistent with the present invention. On the contrary, they are merely examples of an apparatus and a method consistent with some aspects of the present invention as described in detail in the appended claims.

The terms “include” and “have” in the present invention are used to indicate an open-ended inclusion, and that additional elements, components, or the like may be present in addition to the listed ones. The terms “first”, “second”, and the like are used merely for differentiation, rather than limiting the number of objects. In addition, different elements and regions in the accompanying drawings are merely schematic illustrations, and thus the present invention is not limited to the dimensions or distances shown in the accompanying drawings.

The technical solutions of the present invention are described in detail below by using specific embodiments. The following specific embodiments may be combined with each other, and the same or similar concepts or processes may not be repeated in some embodiments. The embodiments of the present invention are described below with reference to the accompanying drawings.

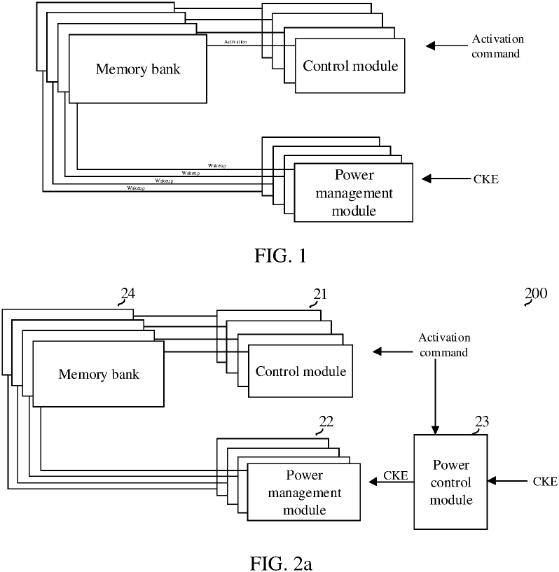

FIG. 1 is an exemplary diagram of a power management architecture of a memory. As shown in FIG. 1, the memory includes a plurality of memory banks, each of which includes a plurality of memory cells for storing data. Each memory bank includes a memory array, and a memory cell can be accurately found by first determining the memory bank and then specifying a row (Row) and a column (Column) of the memory bank.

The memory further includes a control module, also referred to as a local control unit. In practical application, the local control unit may correspond to each memory bank, and control the corresponding memory bank to perform a related operation according to a received activation command (for example, a common Act command). In addition, the memory further includes a power management module, also referred to as local power management. Similarly, in practical application, the power management module may correspond to each memory bank, and perform a management function, including but not limited to wakeup, on a local power supply for the corresponding memory bank.

Taking the above architecture as an example, in a power control manner, wakeup of power supplies for the memory banks is controlled based on a clock enable signal CKE. For example, when the memory enters a precharge power down (precharge power down) state, which is controlled by a clock enable signal, power management modules for all the memory banks control, in response to the current clock enable signal, local power supplies for the memory banks to enter a dormant mode. When the memory exits the precharge power down state and enters a precharge idle state (which is also controlled by a clock enable signal), the power management modules for all the memory banks control, in response to the current clock enable signal, the local power supplies for the memory banks to be woken up. The local power supplies for all the memory banks are woken up to enter an operating mode, and wait to receive an operation of an activation command (Active command).

It is found that based on the above power control manner, even if only one memory bank is selected, the local power supplies for all memory banks are woken up. Although an I_{DD2P} current (Maximum Precharge Power-Down Standby Current) is reduced, an I_{DD2N}/I_{DD3N} current (Maximum Precharge Standby Current/Maximum Active Standby Current) is not effectively reduced.

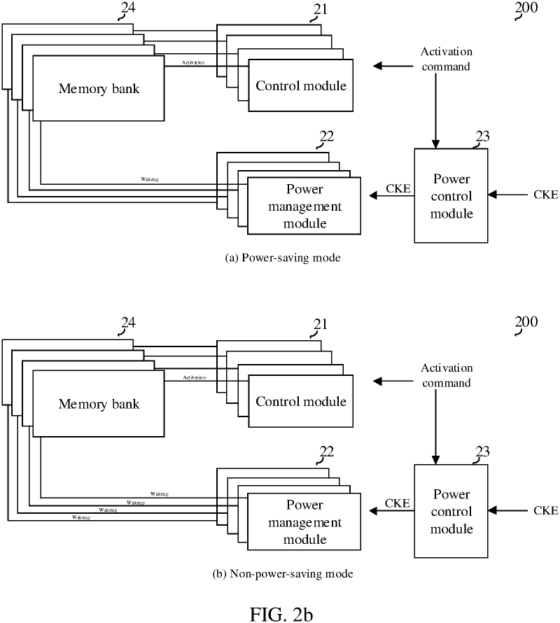

FIG. 2a is a schematic structural diagram of a power control circuit according to an embodiment of the present invention. The power control circuit provided in this embodiment is used to reduce power consumption of a memory. As shown in FIG. 2a, the power control circuit 200 includes: a control module 21 configured to control, according to an activation command, a memory bank 24 to perform an operation; a power management module 22 configured to wake up a local power supply for the memory bank 24 according to a clock enable signal; and a power control module 23 communicatively coupled with the power management module 22 and configured to: select to send the clock enable signal to the power management module for the memory bank corresponding to the activation command in a power-saving mode; and send the clock enable signal to power management modules for all memory banks in a non-power-saving mode, where the power-saving mode indicates that a register is configured to meet a predetermined low-frequency condition.

In practical application, the power control circuit provided in this embodiment may be applied to various memories. As an example, the power control circuit may be applied to, but is not limited to, a double data rate synchronous dynamic random access memory (Double Data Rate Synchronous Dynamic Random Access Memory, DDR SDRAM for short), and the like.

The low-frequency condition indicates that the current operating frequency of an external system clock of the memory is relatively low. The register is a mode register. In practical application, different functions, features, and modes are implemented through programming in the mode registers on DDR chips for application flexibility. As an example, the mode registers can include MR0, MR1, MR2, and MR3. MR0 is used to store data for different operating modes of DDR (e.g., burst length, read burst type, read CAS latency length, test mode, delayed lock loop (DLL) reset, etc.). MR1 is used to store DLL enable, output drive length, extra length, write level enable, etc. MR2 is used to store characteristics for update control and CAS write length. MR3 is used to control multi-purpose registers (MPR).

In one example, the low-frequency condition includes that the register is configured to enable a 16Bank mode. In practical application, DDR can support at least three Bank-Group modes, such as 4Bank mode, 8Bank mode, and 16Bank mode, and thus has a flexible memory bank architecture for users to choose from based on their traffic patterns. Bank-group modes are suitable for speeds above 3200 Mbps and support burst lengths of 16 and 32 beats. The 8Bank mode supports all speeds with a burst length of 32 beats, while the 16Bank mode supports speeds up to 3200Mbps with a burst length of 16 or 32 beats. In other words, when the memory is operating in 16Bank mode, it can generally indicate that the frequency of the current system clock is relatively low.

In another example, the low-frequency condition includes that the register is configured to enable a dynamic voltage and frequency scaling mode. In practical application, DDR with a dynamic voltage and frequency scaling core (DVFSC) has three sets of voltages, namely VDD1, VDD2, and VDDQ. VDD2 further includes VDD2H and VDD 2L. DVFSC may be enabled based on the data stored in the register to switch VDD2H and VDDQ to lower voltages of 0.9 V and 0.3 V to reduce power consumption, when the memory is operating at low speed. In other words, when the DVFSC is enabled, it can also indicate that the frequency of the current system clock is relatively low.

FIG. 2b shows an exemplary power control circuit operating in a power-saving mode and a non-power-saving mode. With reference to a scenario example, when the frequency of the system clock is relatively low, the clock cycle is relatively long and can cover the time length required for the power wakeup response. The time length required for the power wakeup response herein is a time length required for an entire process from reception of the activation command, after which the power control module determines, according to the activation command, a memory bank requiring wakeup, and controls the clock enable signal to reach the power management module for the memory bank, until the local power supply for the memory bank is woken up by the power management module.

In this embodiment, when the configuration of the register meets the low-frequency condition, it indicates that the frequency of the system clock is relatively low and can support a time length required for selecting a memory bank for wakeup. Thus, a selective-wakeup power control strategy is used, namely, the power-saving mode described in this embodiment. With the selective-wakeup power control strategy, the power control module selects only the memory bank corresponding to the activation command for power wakeup, and for other memory banks that are not selected by the activation command, their local power supplies do not need to be woken up, which effectively reduces power consumption of the memory while ensuring proper operation of the memory.

Similarly, with reference to the scenario example, when the configuration of the register doesn’t meet the low-frequency condition, it indicates that the frequency of the system clock is relatively high and the clock cycle is relatively short, and the foregoing solution of selecting the memory bank for power wakeup may not be supported. This is because, to ensure proper operation of the memory, it is usually desirable to complete the power wakeup for the memory before a next system clock arrives. Accordingly, in this case, an all-wakeup power control strategy is used, namely, the non-power-saving mode described in this embodiment. In other words, when the frequency of the system clock is relatively high, the proper operation of the memory needs to be ensured, and therefore, the all-wakeup power control strategy with the shortest time consumption is used. With the all-wakeup power control strategy, the power control module does not need to determine a selected memory bank, but directly transmits the clock enable signal to the power management modules for all the memory banks, which consumes a short time, and can adapt to a high-frequency system clock, thereby ensuring the proper operation of the memory.

In practical application, the activation command may be output to a control module for a memory bank at a corresponding address by a command decoding control module after the address is decoded by the command decoding control module, to instruct the selected memory bank to perform an operation, for example, including but not limited to read/write. In an example, a rising edge of a differential clock signal corresponding to the activation command represents information about the selected memory bank. This example is illustrated with reference to an activation command truth table shown in Table 1.

TABLE 1

| SDRAM COMMAND | BK ORG (BG, 16B, 8B) | SDR CMD PIN | DDR COMMAND PINS | | | | | | | Ck_t edge | Notes |
|---|---|---|---|---|---|---|---|---|---|---|---|
| | | CS | CA0 | CA1 | CA2 | CA3 | CA4 | CA5 | CA6 | | |
| DESELECT (DES) | Any | L | X | X | X | X | X | X | X | [image] | 1, 2 |
| | | X | X | X | X | X | X | X | X | [image] | |
| NO OPERATION (NOP) | Any | H | L | L | L | L | L | L | L | [image] | 1, 2 |
| | | X | X | X | X | X | X | X | X | [image] | |
| POWER DOWN ENTRY (PDE) | Any | H | L | L | L | L | L | L | H | [image] | 1, 2, 12 |
| | | L | X | X | X | X | X | X | X | [image] | |
| ACTIVATE-1 (ACT-1) | Any | H | H | H | H | R14 | R15 | R16 | R17 | [image] | 1, 2, 3, 4 |
| | BG | X | BA0 | BA1 | BGO | BG1 | R11 | R12 | R13 | [image] | |
| | 16B | | BA0 | BA1 | BA2 | BA3 | | | | | |
| | 8B | | BA0 | BA1 | BA2 | V | | | | | |
| ACTIVATE-2 (ACT-2) | Any | H | H | H | L | R7 | R8 | R9 | R10 | [image] | 1, 2, 4 |
| | | X | R0 | R1 | R2 | R3 | R4 | R5 | R6 | [image] | |

The first column represents command states of the memory. The second column represents an architecture of the memory bank. The third column and DDR COMMAND PINS represent chip select signals and various pin signals in different command states. For example, H represents a high level, and L represents a low level.

CK_t and CK_c are differential clock signals. In practical application, all address and control input signals are sampled at an intersection of a rising edge of CK_t and a falling edge of CK_c. It can be learned that, in the truth table, the memory bank corresponding to the activation command can be determined at a falling edge moment of a differential clock signal under an ACT-1 command. BA0 represents an address of a memory bank 0, and this is true for BA1 to BA3. BG0 and BG1 each represent an address of a memory bank group (bank group). Therefore, in an example, the addresses of the memory banks in the truth table may be replaced with R14 to R17 corresponding to a rising edge of the differential clock signal under the ACT-1 command. A specific replacement method is not limited. According to the truth table after the replacement, the memory bank corresponding to the activation command can be known earlier than that before the replacement, thereby advancing a power wakeup time. In this way, the power-saving mode can more reliably adapt to the system clock, so as to ensure reliable operation of the memory and expand the frequency of the system clock suitable for the power-saving mode.

In this embodiment, the power control module switches to the power-saving mode or the non-power-saving mode based on a state of the system clock, and may select to send a clock enable signal CKE to power management modules for some memory banks or all memory banks, so that a corresponding power management module wakes up the local power supply for the memory bank in response to the clock enable signal, and the control module controls, in response to the activation command, the memory to perform an operation, to implement a function of the memory. Based on the power control circuit, a power management mode can be switched. In the power-saving mode, only a local power supply for a selected memory bank needs to be woken up; and in the non-power-saving mode, local power supplies for all memory banks are woken up, thereby improving flexibility of power wakeup management and reducing power consumption.

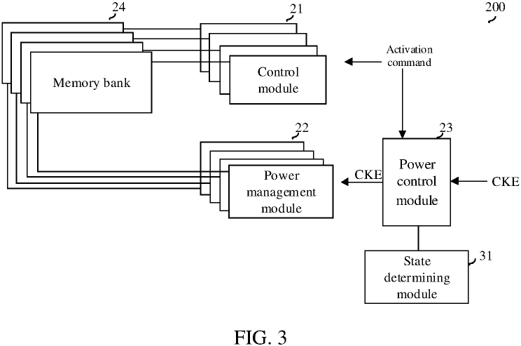

In some embodiments of the present invention, FIG. 3 is a schematic structural diagram of a power control circuit according to an embodiment of the present invention, which provides a related example of a mode switching strategy of the power control module. As shown in FIG. 3, the power control circuit 200 further includes a state determining module 31.

In some embodiments of the present invention, a state determining module 31 is communicatively coupled with the register (not shown in the figure) and the power control module 23 and is configured to control the power control module 23 to switch to the power-saving mode or the non-power-saving mode based on the configuration parameter of the register.

In some embodiments of the present invention, the operating frequency of the memory can be determined by the configuration parameter of the register. For example, Table 2 is a configuration parameter table of the register of a certain memory. As shown in Table 2, different rows provide the parameters of the registers of the memory at different processing speeds, while the sixth column lists the upper limit of the clock frequency.

TABLE 2

| MR2 OP[3:0] | Data Rate Lower Limit (Mbps) | Data Rate Upper Limit (Mbps) | WCK: CK Ratio | Lower Clock Frequency Limit (>) (MHz) | Upper Clock Frequency Limit (<=) (MHz) | Read Latency | | | nRBTP [nCK] |
|---|---|---|---|---|---|---|---|---|---|
| | | | | | | Set 0 | Set 1 | Set 2 | |
| 0000_{B} | 40 | 533 | 2: 1 | 10 | 133 | 6 | 6 | 6 | 0 |
| 0001_{B} | 533 | 1067 | | 133 | 267 | 8 | 8 | 8 | 0 |
| 0010_{B} | 1067 | 1600 | | 267 | 400 | 10 | 10 | 12 | 0 |
| 0011_{B} | 1600 | 2133 | | 400 | 533 | 12 | 14 | 14 | 0 |
| 0100_{B} | 2133 | 2750 | | 533 | 688 | 16 | 16 | 18 | 2 |
| 0101_{B} | 2750 | 3200 | | 688 | 800 | 18 | 20 | 20 | 2 |
| 0000_{B} | 40 | 533 | 4: 1 | 5 | 67 | 3 | 3 | 3 | 0 |
| 0001_{B} | 533 | 1067 | | 67 | 133 | 4 | 4 | 4 | 0 |
| 0010_{B} | 1067 | 1600 | | 133 | 200 | 5 | 5 | 6 | 0 |
| 0011_{B} | 1600 | 2133 | | 200 | 267 | 6 | 7 | 7 | 0 |
| 0100_{B} | 2133 | 2750 | | 267 | 344 | 8 | 8 | 9 | 1 |
| 0101_{B} | 2750 | 3200 | | 344 | 400 | 9 | 10 | 10 | 1 |
| 0110_{B} | 3200 | 3733 | | 400 | 467 | 10 | 11 | 12 | 2 |
| 0111_{B} | 3733 | 4267 | | 467 | 533 | 12 | 13 | 14 | 2 |
| 1000_{B} | 4267 | 4800 | | 533 | 600 | 13 | 14 | 15 | 3 |
| 1001_{B} | 4800 | 5500 | | 600 | 688 | 15 | 16 | 17 | 4 |
| 1010_{B} | 5500 | 6000 | | 688 | 750 | 16 | 17 | 19 | 4 |
| 1011_{B} | 6000 | 6400 | | 750 | 800 | 17 | 18 | 20 | 4 |

Assume that the power-saving mode is adopted when the frequency of the system clock is not higher than 400 MHz, while the non-power-saving mode is adopted when the frequency of the system clock is higher than 400 MHz. The state determining module 31 may read relevant configuration parameters from the register, determine the current operating frequency of the memory based on the configuration parameters (i.e., whether the frequency of the system clock is lower than 400 MHz), and then control the power control module to switch to the power-saving mode or the non-power-saving mode.

As an example, the state determining module 31 is configured to obtain an upper limit of the clock frequency from the configuration parameters of the register, and control the power supply control module to switch to the power-saving mode when the upper limit of the clock frequency is not higher than a predetermined value. As another example, the upper limit of the clock frequency may also be determined based on the three parameters (i.e., Set0 to Set2) under the column of Read Latency in the above register configuration parameter table. Correspondingly, the state determining module 31 is configured to obtain a read latency parameter from the configuration parameters of the register, and control the power supply control module to switch to the power saving mode when the upper limit of the clock frequency corresponding to the read latency parameter is not higher than the predetermined value. Therefore, the power control module is controlled to switch to the power-saving mode or the non-power-saving mode based on the read latency parameter.

With reference to the scenario example, when the state determining module 31 obtains an upper limit of the clock frequency from the configuration parameter of the register and determines that the upper limit of the clock frequency is not greater than a predetermined value, the power control module 33 is controlled to switch to the power-saving mode. In the power-saving mode, the power control module 23 selects only the memory bank corresponding to the activation command for power wakeup, and for other memory banks that are not selected by the activation command, their local power supplies do not need to be woken up, which effectively reduces power consumption of the memory while ensuring proper operation of the memory. When the state determining module 31 determines that the upper limit of the clock frequency is greater than a predetermined value, the power control module 23 is controlled to switch to the non-power-saving mode. In the non-power-saving mode, the power control module directly transmits the clock enable signal to the power management modules for all the memory banks, which consumes a short time, and can adapt to a high-frequency system clock, thereby ensuring the proper operation of the memory.

In some embodiments, a manner in which the state determining module 31 controls the power control module 23 to switch to the power-saving mode or the non-power-saving mode is sending, by the state determining module 31, a first signal to the power control module 23 to instruct the power control module 23 to switch to the power-saving mode; or sending a second signal to the power control module 23 to enable the power control module 23 to switch to the non-power-saving mode. In other words, the first signal represents the power-saving mode, and the second signal represents the non-power-saving mode.

In some embodiments, the first signal and the second signal may be transmitted through different ports, and the power control module determines, based on a port through which the signal is currently received, a mode to which the power control module currently needs to switch. For example, it is assumed that the first signal and the second signal are both high-level signals, except that the first signal is received through a first port, and the second signal is received through a second port. For the power control module, when the first port receives the high-level signal, the power control module switches to the power-saving mode; when the second port receives the high-level signal, the power control module switches to the non-power-saving mode.

In some embodiments, the first signal and the second signal may be different signals transmitted through a port, and the power control module determines, based on a signal currently received through the port, a mode to which the power control module currently needs to switch. For example, it is assumed that the first signal and the second signal are received through the first port, the first signal is a high-level signal, and the second signal is a low-level signal. For the power control module, when the first port receives the high-level signal, the power control module switches to the power-saving mode; when the first port receives the low-level signal, the power control module switches to the non-power-saving mode.

In this embodiment, the state determining module controls the power control module to switch to the power-saving mode or the non-power-saving mode based on the configuration of the register. In this way, based on the currently switched mode, the power control module selects to send a clock enable signal to power management modules for some or all memory banks, so that a corresponding power management module wakes up the local power supply for the memory bank in response to the clock enable signal, and the control module controls, in response to the activation command, the memory to perform an operation, to implement a function of the memory. Based on the power control circuit, a power management mode can be switched. In the power-saving mode, only a local power supply for a selected memory bank needs to be woken up; and in the non-power-saving mode, local power supplies for all memory banks are woken up, thereby improving flexibility of power wakeup management and reducing power consumption.

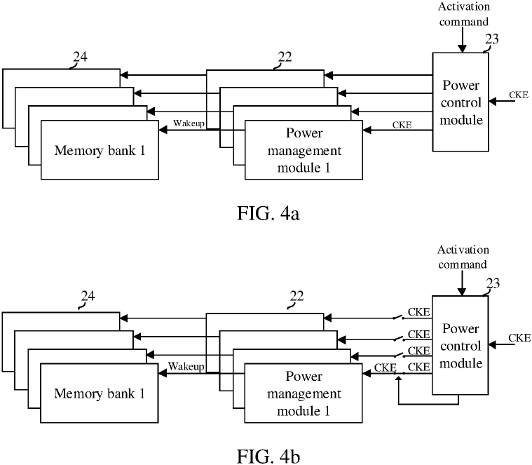

As an example, FIG. 4a and FIG. 4b show exemplary implementations of the power control module. It should be noted that in the figures, a connection between the power control module and the power management module are mainly taken as an example for description. For modules and structures (such as the control module) not shown in the figures, refer to the previous content.

When the power control module is in the power-saving mode, a local power supply for a selected memory bank may be woken up. In an example, the power control module may select to send a clock enable signal to a power management module corresponding to the selected memory bank, to better adapt to the general memory architecture without making excessive changes.

With reference to the scenario example, in the power-saving mode, the power control module 23 selects the memory bank 24 corresponding to the activation command for power wakeup, and for other memory banks 24 that are not selected by the activation command, their local power supplies do not need to be woken up, which effectively reduces power consumption of the memory while ensuring proper operation of the memory.

In an example, in the power-saving mode, the power control module 23 selects to send the clock enable signal to the power management module 22 for the memory bank 24 corresponding to the activation command by controlling a port that outputs the clock enable signal. It should be noted that the structures not shown in the figures are similar to those in the foregoing embodiment, and details are not further described.

Referring to FIG. 4a, for example, the power control module 23 has a plurality of output ports, including output ports in a one-to-one correspondence with the power management modules 22 for the memory banks 24. Assuming that it is determined according to the activation command that a memory bank 1 is selected this time, in the power-saving mode, the power control module 23 wakes up only a local power supply for the memory bank 1. Correspondingly, the power control module 23 transmits a clock enable signal to a power management module 1 for the memory bank 1 through an output port 1 corresponding to the power management module 1 for the memory bank 1, and output ports corresponding to the other power management modules do not output signals. Therefore, the power management module 1 wakes up the local power supply for the memory bank 1 in response to the received clock enable signal.

In another example, a controllable switch is provided between the power control module 23 and each of the power management modules 22; and in the power-saving mode, the power control module 23 selects to send the clock enable signal to the power management module 22 for the memory bank 24 corresponding to the activation command by controlling controllable switches corresponding to different power management modules 22 to be on or off.

For example, referring to FIG. 4b, a controllable switch is provided on a path between the power control module 23 and the power management module 22 for each memory bank 24. States of these controllable switches are controlled by the power control module 23. Assuming that it is determined according to the activation command that a memory bank 1 is selected this time, in the power-saving mode, the power control module 23 wakes up only a local power supply for the memory bank 1. Correspondingly, the output ports of the power control module 23 all output the clock enable signal, but the power control module 23 selects to control a controllable switch corresponding to the power management module 1 for the memory bank 1 to be on, and controllable switches corresponding to the other power management modules to be all off, to select to transmit the clock enable signal to the power management module 1 for the memory bank 1. Therefore, the power management module 1 wakes up the local power supply for the memory bank 1 in response to the received clock enable signal.

In this embodiment, in the power-saving mode, the power control module selects to send the clock enable signal to the power management module for the selected memory bank, so that a corresponding power management module wakes up the local power supply for the memory bank in response to the clock enable signal, and the control module controls, in response to the activation command, the memory to perform an operation, to implement a function of the memory. Based on the power control circuit, a power management mode can be switched. In the power-saving mode, only the local power supply for the selected memory bank needs to be woken up, thereby improving flexibility of power wakeup management and reducing power consumption.

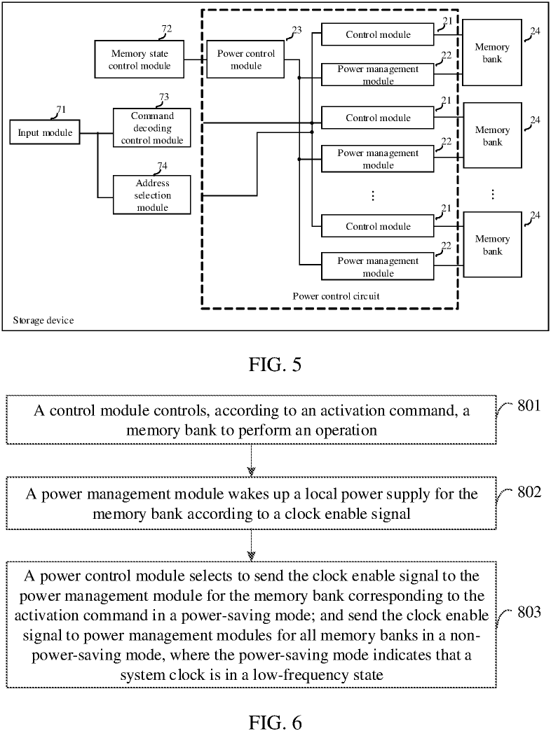

FIG. 5 is a schematic structural diagram of a storage device according to an embodiment of the present invention. As shown in FIG. 5, the storage device includes: an input module 71, a memory state control module 72, a command decoding control module 73, an address selection module 74, and the power control circuit described above.

The input module 71 receives various commands, including but not limited to, an activation command, an address, a control input signal, and the like. The memory state control module 72 outputs a clock enable signal CKE based on a state of a memory. In practice, an internal clock signal and a device input buffer and an output driver activate CKE HIGH and disable CKE Low. Setting CKE to low can provide precharge power down and self-refresh operations (all memory banks are idle), or effective power-down (there are memory banks in an active state). CKE is maintained at a high level throughout a read/write access.

The command decoding control module 73 parses the command transmitted by the input module 71, and sends an activation command to a control module 21 for a selected memory bank 24. The address selection module 74 may determine an address of a selected memory cell based on the command and signal transmitted by the input module 71 to activate a row and a column of the memory cell. It should be noted that the figure is merely an example, and for the structure and working principle of each circuit in this embodiment, refer to the related content in the foregoing embodiment.

Taking the scenario of the power-saving mode as an example, when the memory is activated to operate, the command decoding control module 73 transmits the activation command to the power control module 23, and the memory state control module 72 transmits the clock enable signal to the power control module 23. The power control module 23 in the power-saving mode determines the selected memory bank 24 according to the activation command, transmits the clock enable signal to the power management module 22 for the memory bank 24, and does not wake up local power supplies for the other memory banks 24. Taking the scenario of the non-power-saving mode as an example, when the memory is activated to operate, the command decoding control module 73 transmits the activation command to the power control module 23, and the memory state control module 72 transmits the clock enable signal to the power control module 23. The power control module 23 in the non-power-saving mode directly transmits the clock enable signal to the power management modules 22 for all the memory banks 24, to wake up the local power supplies for all the memory banks. In an example, the power-saving mode/non-power-saving mode may be determined by the foregoing state determining module.

In this embodiment, the power control module of the storage device may switch to the power-saving mode or the non-power-saving mode based on a state of the system clock, and select to send a clock enable signal to power management modules for some or all memory banks, so that a corresponding power management module wakes up the local power supply for the memory bank in response to the clock enable signal, and the control module controls, in response to the activation command, the memory to perform an operation, to implement a function of the memory. Based on the power control circuit, a power management mode can be switched. In the power-saving mode, only a local power supply for a selected memory bank needs to be woken up; and in the non-power-saving mode, local power supplies for all memory banks are woken up, thereby improving flexibility of power wakeup management and reducing power consumption.

FIG. 6 is a schematic flowchart of a power control method according to an embodiment of the present invention. The power control method is applicable to the structure as described in any one of the foregoing examples. The method includes the following steps:

Step 801: A control module controls, according to an activation command, a memory bank to perform an operation.

Step 802: A power management module wakes up a local power supply for the memory bank according to a clock enable signal.

Step 803: A power control module selects to send the clock enable signal to the power management module for the memory bank corresponding to the activation command in a power-saving mode; and send the clock enable signal to power management modules for all memory banks in a non-power-saving mode, where the power-saving mode indicates that a register is configured to meet a predetermined low-frequency condition.

In an example, the low-frequency condition comprises that the register is configured to enable a 16Bank mode. Optionally, the low-frequency condition comprises that the register is configured to enable a dynamic voltage and frequency scaling mode.

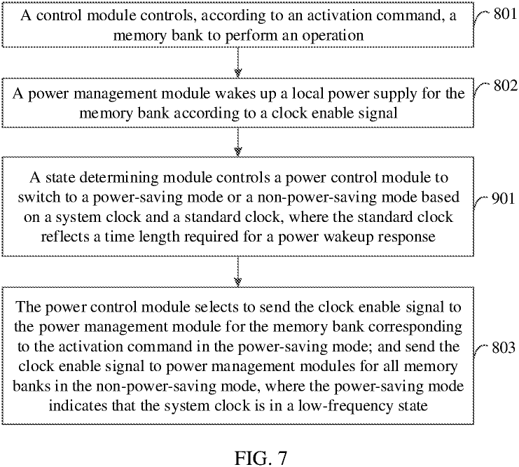

Optionally, as shown in FIG. 7, to control the mode switching of the power control module, the method further includes the following step:

Step 901: The state determining module controls the power control module to switch to the power-saving mode or the non-power-saving mode based on the configuration parameter of the register.

In an example, step 901 may include: the state determining module obtains an upper limit of the clock frequency from the configuration parameter of the register, and control, in response to the upper limit of the clock frequency being not greater than a predetermined value, the power control module to switch to the power-saving mode.

Still optionally, controlling, by the state determining module, the power control module to switch to the power-saving mode or the non-power-saving mode includes: sending, by the state determining module, a first signal to the power control module to instruct the power control module to switch to the power-saving mode; and sending a second signal to the power control module to instruct the power control module to switch to the non-power-saving mode.

With reference to the scenario example, when the state determining module determines that the configuration of the register meets any of the low-frequency conditions, for example, being configured to enable a 16Bank mode or a dynamic voltage and frequency scaling mode, or the clock frequency determined by the configuration parameter is not greater than a predetermined value, the power control module is controlled to switch to the power-saving mode. In the power-saving mode, the power control module selects only the memory bank corresponding to the activation command for power wakeup, and for other memory banks that are not selected by the activation command, their local power supplies do not need to be woken up, which effectively reduces power consumption of the memory while ensuring proper operation of the memory. When the state determining module determines that the configuration of the register fails to meet the low-frequency conditions, for example, not being configured to enable a 16Bank mode or a dynamic voltage and frequency scaling mode, or the clock frequency determined by the configuration parameter is greater than a predetermined value, the power control module is controlled to switch to the non-power-saving mode. In the non-power-saving mode, the power control module directly transmits the clock enable signal to the power management modules for all the memory banks, which consumes a short time, and can adapt to a high-frequency system clock, thereby ensuring the proper operation of the memory.

In one manner, the power control module determines, based on a port through which the signal is currently received, a mode to which the power control module currently needs to switch. In another manner, the power control module determines, based on a currently received signal level, a mode to which the power control module currently needs to switch.

In an example, in the power-saving mode, the power control module selects to send the clock enable signal to the power management module for the memory bank corresponding to the activation command by controlling a port that outputs the clock enable signal.

In another example, in the power-saving mode, the power control module selects to send the clock enable signal to the power management module for the memory bank corresponding to the activation command by selecting to control controllable switches between different power management modules and the power control module to be on or off.

In this embodiment, the power control module switches to the power-saving mode or the non-power-saving mode based on the configuration of the register, and may select to send a clock enable signal to power management modules for some or all memory banks, so that a corresponding power management module wakes up the local power supply for the memory bank in response to the clock enable signal, and the control module controls, in response to the activation command, the memory to perform an operation, to implement a function of the memory. Based on the power control circuit, a power management mode can be switched. In the power-saving mode, only a local power supply for a selected memory bank needs to be woken up; and in the non-power-saving mode, local power supplies for all memory banks are woken up, thereby improving flexibility of power wakeup management and reducing power consumption.

Persons skilled in the art may easily figure out other implementation solutions of the present invention after considering the specification and practicing the invention disclosed herein. The present invention is intended to cover any variations, purposes, or adaptive changes of the present invention. Such variations, purposes, or applicable changes follow the general principle of the present invention and include common knowledge or conventional technical means in the art which is not disclosed in the present invention. The specification and embodiments are merely considered as examples, and the true scope and spirit of the present invention are defined by the appended claims.

It should be understood that the present invention is not limited to the exact structure that has been described above and shown in the accompanying drawings, and various modifications and changes may be made without departing from the scope of the present invention. The scope of the present invention is defined only by the appended claims.

What is claimed is:

1. A power control circuit, comprising:
a control module configured to control, according to an activation command, a memory bank of a plurality of memory banks to perform an operation;
a power management module configured to wake up a local power supply for the memory bank according to a clock enable signal; and
a power control module communicatively coupled with the power management module and configured to:
send the clock enable signal to the power management module of the memory bank corresponding to the activation command in a power-saving mode, and
send the clock enable signal to power management modules of the plurality of memory banks in a non-power-saving mode, wherein the power-saving mode indicates that a register is configured to meet a predetermined low-frequency condition.

2. The power control circuit of claim 1, wherein:
the plurality of memory banks are dynamic random access memory (DRAM), and
the low-frequency condition comprises that the register is configured to enable a 16Bank mode.

3. The power control circuit of claim 1, wherein the low-frequency condition comprises that the register is configured to enable a dynamic voltage and frequency scaling mode.

4. The power control circuit of claim 1, further comprising:
a state determining module communicatively coupled with the register and the power control module and configured to control the power control module to switch to the power-saving mode or the non-power-saving mode based on a configuration parameter of the register.

5. The power control circuit of claim 4, wherein the state determining module is configured to:
send a first signal to the power control module to instruct the power control module to switch to the power-saving mode; and
send a second signal to the power control module to instruct the power control module to switch to the non-power-saving mode.

6. The power control circuit of claim 4, wherein the state determining module is configured to:
obtain an upper limit of a clock frequency from the configuration parameter of the register, and
control, in response to the upper limit of the clock frequency being not greater than a predetermined value, the power control module to switch to the power-saving mode.

7. The power control circuit of claim 1, wherein the activation command is output, by a command decoding control module, to a control module of a memory bank from the plurality of memory banks at a corresponding address after the address is decoded by the command decoding control module.

8. The power control circuit of claim 1, wherein in the power-saving mode, the power control module is configured to send the clock enable signal to the power management module of the memory bank corresponding to the activation command by controlling a port that outputs the clock enable signal.

9. The power control circuit of claim 1, further comprising a plurality of controllable switches, each controllable switch being between the power control module and each of the power management modules of the plurality of memory banks,
wherein in the power-saving mode, the power control module is configured to send the clock enable signal to the power management module of the memory bank corresponding to the activation command by controlling at least some of the plurality of controllable switches to be on or off.

10. A power control method, applicable to a power control circuit comprising a control module, a power management module, and a power control module, comprising:
controlling, by the control module according to an activation command, a memory bank of a plurality of memory banks to perform an operation;
waking up, by the power management module, a local power supply of the memory bank according to a clock enable signal;
sending, by the power control module, the clock enable signal to the power management module of the memory bank corresponding to the activation command in response to a power-saving mode; and
sending, by the power control module, the clock enable signal to power management modules of the plurality of memory banks in response to a non-power-saving mode, wherein the power-saving mode indicates that a register is configured to meet a predetermined low-frequency condition.

11. The method of claim 10, wherein the low-frequency condition comprises that the register is configured to enable a 16Bank mode.

12. The method of claim 10, wherein the low-frequency condition comprises that the register is configured to enable a dynamic voltage and frequency scaling mode.

13. The method of claim 10, wherein the power control circuit further comprises a state determining module, and the method further comprises:
controlling, by the state determining module, the power control module to switch to the power-saving mode or the non-power-saving mode based on a configuration parameter of the register.

14. The method of claim 13, wherein the controlling, by the state determining module, the power control module to switch to the power-saving mode or the non-power-saving mode comprises:
sending, by the state determining module, a first signal to the power control module to instruct the power control module to switch to the power-saving mode; and sending a second signal to the power control module to instruct the power control module to switch to the non-power-saving mode.

15. The method of claim 13, wherein controlling, by the state determining module, the power control module to switch to the power-saving mode or the non-power-saving mode based on the configuration parameter of the register comprises:
obtaining, by the state determining module, an upper limit of a clock frequency from the configuration parameter of the register, and
controlling, by the state determining module, the power control module to switch to the power-saving mode in response to the upper limit of the clock frequency being not greater than a predetermined value.
